(19) United States
(12) Patent Application Publication
(10) Pub. No.: US 2009/0201660 A1
(43) Pub. Date: Aug. 13, 2009

(54) CONTROL BOARD ASSEMBLY AND DISPLAY DEVICE HAVING THE SAME

(76) Inventor: SANG-YOUN KIM, Chunan-si (KR)

Correspondence Address: F. CHAU & ASSOCIATES, LLC, 130 WOODBURY ROAD, WOODBURY, NY, 11797, US

(21) Appl. No.: 12/241,817

(22) Filed: Sep. 30, 2008

(30) Foreign Application Priority Data
Feb. 12, 2008 (KR) 10-2008-0012675

(51) Int. Cl. H05K 9/00

(52) U.S. Cl. 361/818

(57) ABSTRACT

A control board assembly includes a board, at least one electronic component mounted on one surface of the board, and a shield case receiving therein the board on which the at least one electronic component is mounted. On one surface of the shield case facing the at least one electronic component, at least one opening is formed to expose the at least one electronic component.

### CROSS-REFERENCE TO RELATED APPLICATION

This application is based on and claims priority from Korean Patent Application No. 10-2008-0012675, filed on Feb. 12, 2008, the disclosure of which is incorporated by reference herein.

### BACKGROUND OF THE INVENTION

1. Technical Field

The present disclosure relates to a display device, and more particularly to a display device that can remove electromagnetic interference (EMI) noise of a low frequency band by changing a shield case structure.

2. Discussion of the Related Art

Generally, a liquid crystal display (LCD) has a smaller size, a lighter weight, and a larger screen than a cathode ray tube (CRT), and thus its development has been rapid. In particular, LCDs have been developed to serve as flat display devices, and have been used not only in cellular phones, PDAs, digital cameras, and camcorders, but also in monitors of desktop computers and large-scale display devices. The range of uses of LCDs has been expanded rapidly.

Drive signals for driving a liquid crystal display (LCD) panel are provided through a control board formed on a printed circuit board (PCB) attached to a rear surface of a backlight assembly. However, the control board produces electromagnetic interference (EMI). Accordingly, a shield case for shielding the EMI generated by the control board is provided to restrict the control board to an airtight space, and to prevent the EMI generated by the control board from affecting the LCD.

In order to provide the drive signals required to drive the LCD panel, a plurality of electronic components, such as a timing controller (T-CON), a memory chip, capacitors, resistors, and the like, are mounted on the control board. However, spaces between the respective electronic components and a metal shield case covering the control board may vary, and the EMI generated from the respective electronic components may also vary. Accordingly, resonances are generated between the respective electronic components and the shield case, and EMI exceeding a standard value is generated in a particular area causing an abrupt increase of noise. This EMI noise may cause a malfunction of the LCD. In particular, the EMI noise in a low frequency band may cause malfunctions.

### SUMMARY OF THE INVENTION

Accordingly, embodiments of the present invention seek to provide a control board assembly and a display device having the same, which can prevent a malfunction of a display panel by shielding EMI generated in a control board and removing an EMI noise being generated between the control board and a shield case.

Further embodiments of the present invention provide a control board assembly and a display device having the same, which can prevent a malfunction of a display panel by reducing EMI generated in a control board using a plate type member.

Still further embodiments of the present invention provide a control board assembly and a display device having the same, which can prevent a malfunction of a display panel by removing an EMI noise being generated between a plate type member arranged on an upper portion of an exposed control board and other metal components neighboring the control board.

A control board assembly, according to an embodiment of the present invention, includes a board; at least one electronic component mounted on one surface of the board; and a shield case receiving therein the board on which the at least one electronic component is mounted. On one surface of the shield case facing the at least one electronic component, at least one opening is formed to expose the at least one electronic component.

On one side of the opening, a plate type member may be provided. The plate type member may be coupled to an upper portion or a lower portion of the shield case. Also, the plate type member may be an insulating member, and may be an insulating tape. The electronic component may include a timing controller.

A connection part for transmitting an external signal may be formed on one side of the one surface of the board. A first aperture may be formed in the shield case to expose the connection part. A second plate type member may be provided on one side of the first aperture. The second plate type member may be coupled to an upper portion of the first aperture. The second plate type member may be one of a metal member or an insulating member.

A plurality of electronic components may be mounted on the board, and a plurality of openings may be formed to expose the plurality of electronic components. The number of openings may correspond to the number of electronic components. On one side of the shield case, a plate type member may be provided to cover the opening. The number of plate type members may correspond to the number of openings.

A display device, according to an exemplary embodiment of the present invention, includes a display panel displaying an image; a control board providing drive signals to the display panel and having electronic components mounted on one surface thereof; and a shield case receiving therein the control board. On one surface of the shield case facing the electronic components, an opening is formed so as to expose the electronic components.

A plate type member may be provided on one side of the opening, and the plate type member may be coupled to the opening so as to face the electronic components. The plate type member may be an insulating tape. A receiving part receiving the display panel may be provided, and the control board may be arranged on a rear surface of the receiving part. The shield case may be coupled to the rear surface of the receiving part.

### BRIEF DESCRIPTION OF THE DRAWINGS

Exemplary embodiments of the present invention will become apparent by reference to the following detailed description taken in conjunction with the accompanying drawings, wherein:

FIG. 1 is an exploded perspective view of an LCD according to an exemplary embodiment of the present invention;

FIGS. 2 and 3 are perspective views illustrating a shield case coupled to a control board according to an exemplary embodiment of the present invention;

FIGS. 4 to 6 are views illustrating modified examples of a shield case coupled to a control board according to an exemplary embodiment of the present invention; and

FIGS. 7A and 7B are graphs showing results of EMI tests performed on the flat display device according to an exemplary embodiment of the present invention and on a conventional LCD.

### DETAILED DESCRIPTION OF THE PREFERRED EMBODIMENTS

Hereinafter, exemplary embodiments of the present invention will be described in detail with reference to the accompanying drawings. In the description of the exemplary embodiment of the present invention, the same drawing reference numerals are used for the same elements across various figures.

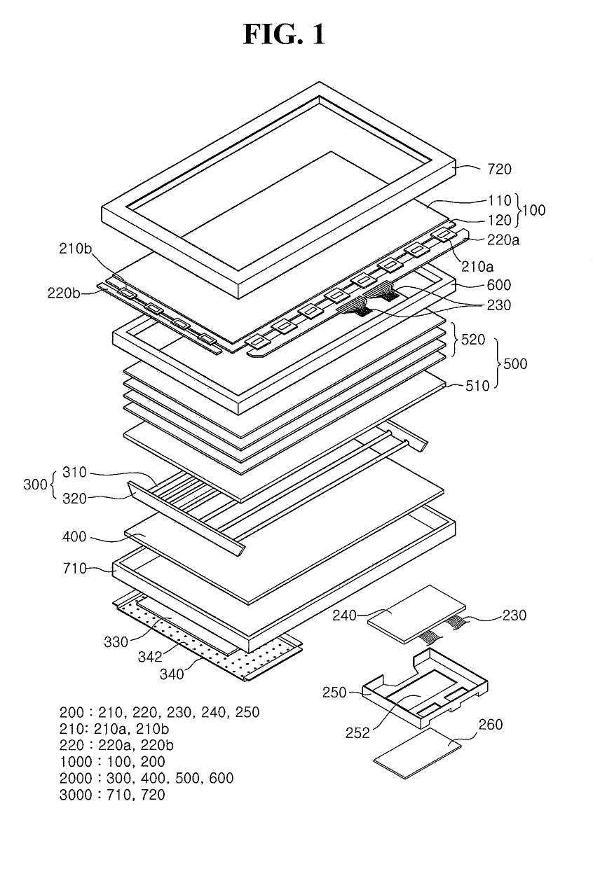

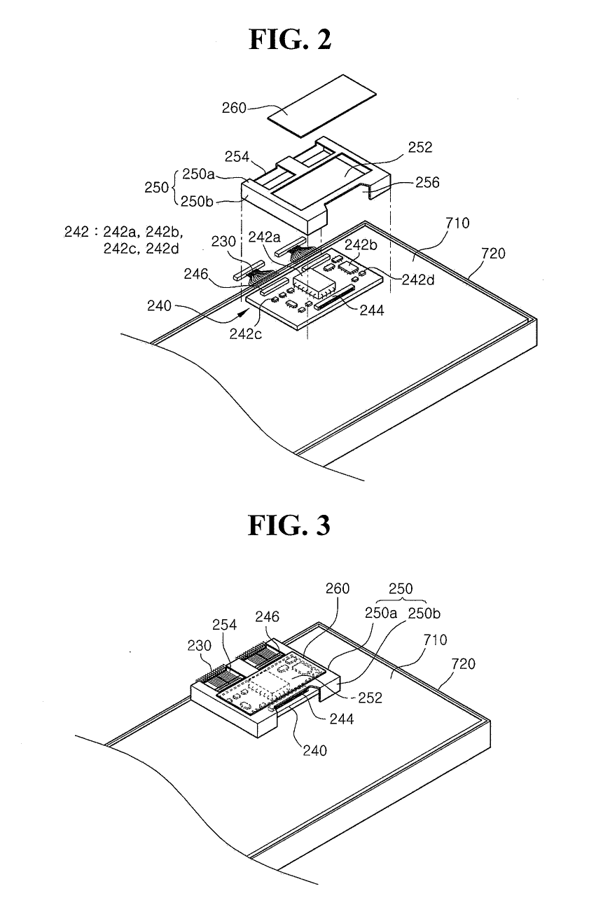

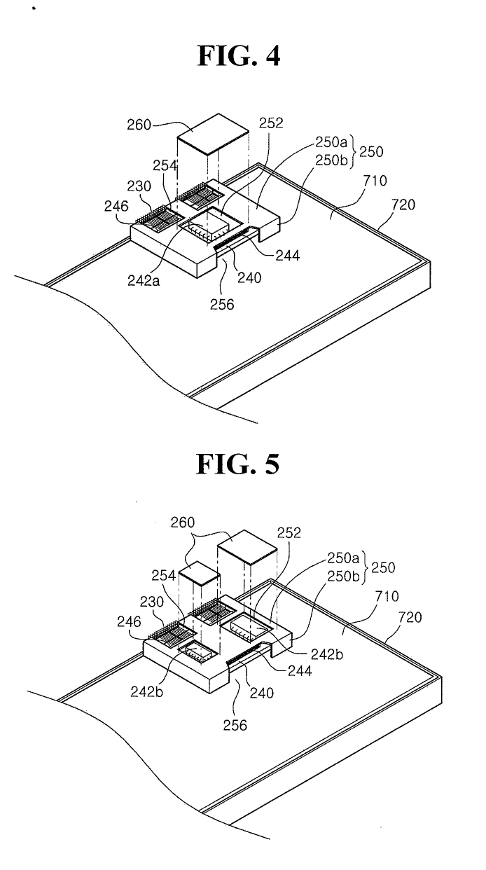

FIG. 1 is an exploded perspective view of an LCD according to an exemplary embodiment of the present invention. FIGS. 2 and 3 are perspective views illustrating a shield case coupled to a control board according to an exemplary embodiment of the present invention, and FIGS. 4 to 6 are views illustrating modified examples of a shield case coupled to a control board according to an exemplary embodiment of the present invention.

Referring to FIG. 1, an LCD includes a display assembly 1000 displaying an image, a backlight assembly 2000 providing light to the display assembly 1000, and a receiving member 300 receiving the display assembly 1000 and the backlight assembly 2000.

The display assembly 1000 includes a liquid crystal display (LCD) panel 100, and a driving part 200 connected to the LCD panel 100 to drive the LCD panel 100.

The LCD panel 100 includes a thin film transistor (TFT) substrate 120 on which a plurality of thin film transistors are formed, a color filter substrate 110 located on an upper portion of the TFT substrate 120, and a liquid crystal layer (not illustrated) formed between the substrates 120 and 110. Polarizing plates (not illustrated) may be formed on an upper portion of the color filter substrate 110 and on a lower portion of the TFT substrate 120, respectively. The polarizing plates may be attached to the color filter substrate 110 and the TFT substrate 120, respectively, to polarize the light.

The TFT substrate 120 is a transparent glass substrate on which the thin film transistors are formed in the form of a matrix, and a data line is connected to a source terminal, while a gate line is connected to a gate terminal. Also, on a drain terminal, a pixel electrode made of indium tin oxide (ITO) as a transparent conductive material is formed. The color filter substrate 110 is arranged to face the TFT substrate 120. The color filter substrate 110 is a substrate on which RGB pixels, which are color pixels generating specified colors as light passes through the pixels, are formed through a thin film process. On a front surface of the color filter substrate, a common electrode made of ITO is formed. When power is supplied to a gate terminal and a source terminal of a thin film transistor and the thin film transistor is turned on, an electric field is formed between the pixel electrode and the common electrode of the color filter substrate 110. By this electric field, an arrangement angle of the liquid crystals injected between the TFT substrate 120 and the color filter substrate 110 is changed, and in accordance with the changed arrangement angle, the light transmittance is changed to obtain a desired image.

The driving part 200 is connected to one side of the LCD panel 100, to drive the LCD panel 100. The driving part 200 includes a printed circuit board (PCB) 220 provided apart from the LCD panel 100, a chip-on-film (COF) type printed circuit board (hereinafter referred to as a “COF PCB”) 210 connecting the PCB 220 and the LCD panel 110, a control board 240 applying drive signals and timing signals to the PCB 220, flexible printed circuits 230 connecting between the PCB 220 and the control board 240, a shield case 250 having an opening 252 formed on one surface thereof to receive and seal up the control board 240, and a plate type member 260 covering the opening 252 formed on the shield case 250.

The PCB 220 is spaced apart from a side or sides of the LCD panel 100, e.g., from a specified side portion of the TFT substrate 120, and includes a data PCB 220a and a gate PCB 220b that correspond to the gate line and the data line formed on the TFT substrate 120, respectively. The COF PCB 210 has a structure connected to the gate line and the data line formed on the TFT substrate 120, and physically and electrically connects the data PCB 220a and the gate PCB 220b to the gate line and the data line, respectively. One end of the flexible printed circuits 230 is connected to the data PCB 220a, and the other end of the flexible printed circuits 230 is connected to the control board 240. The control board 240 is arranged on the rear outer surface of a lower chassis 710 to connect to the flexible printed circuits 230, and in order to prevent a malfunction of the LCD panel because of the EMI generated in the control board 240 to the LCD. The shield case 250 is provided to cover the control board 240. The shield case 250 arranges the control board 240 in a space between the rear surface of the lower chassis 710 and the shield case 250. Also, on one surface of the shield case 250, the opening 252 is formed, and the plate type member 260 is provided on one side of the shield case 250 to cover the opening 252. That is, the shield case 250 having the opening 252 formed thereon and the plate type member 260 serve to remove the EMI and EMI peak noise generated in the control board 240. The coupled structure including the control board 240 and the shield case 250 will be further described later with reference to the accompanying drawings.

When an analog image signal is externally applied to the control board 240, the control board 240 converts the analog image signal into a digital image signal, and the digital image signal is applied to the data PCB 220a and the gate PCB 220b through the flexible printed circuits 230. In order to apply the data drive signals and gate drive signals at a proper time, the data PCB 220a and the gate PCB 220b apply the drive signals to the gate line and the data line of the TFT substrate 120 through a data COF PCB 210a and a gate COF PCB 210b, respectively. Although, in this example, the data PCB 220a and the gate PCB 220b are separated from each other, they may be formed as one PCB. Also, the COF PCB may be of COF type or a TCP type.

The backlight assembly 2000 is provided on the lower portion of the LCD panel 100 and serves to provide light to the LCD panel 100. The backlight assembly 2000 includes a light source part 300, a reflecting plate 400 provided on the lower portion of the light source part 300, optical plates 500 provided on an upper portion of the light source part 300, and a mold frame 600 receiving the reflecting plate 400, the light source part 300, and the optical plates 500 in that order.

The light source part 300 includes a plurality of bar type lamps 310 arranged in parallel, a lamp support part 320 fixedly supporting the plurality of lamps 310, and an inverter 330 supplying a power to the light source part 300. A cold cathode fluorescent lamp (CCFL) is mainly used as the lamp 310, and each respective lamp 310 includes a glass tube, light emitting gases provided in the glass tube, a negative electrode and a positive electrode installed on both end portions of the glass tube. The lamp support part 320 is provided at both ends of the lamps 310 and serves to fix the lamps 310. The inverter 330 that supplies the power to the light source part 300 is provided on the rear surface of the lower chassis 710, and a plurality of inverters may be provided as needed. The inverter 330 is connected to the electrodes formed at both ends of the lamp 310 through conducting wires (not illustrated) and so on to apply the power to the lamp 310. Here, an inverter cover 340 fixing the inverter 330 to the rear surface of the lower chassis 710 may be provided. The inverter cover 340 is fixed to the rear surface of the lower chassis 710 as it covers the inverter 330. Also, a plurality of holes 342 may be formed on the inverter cover 340 to discharge heat generated in the inverter 330 to the outside. Although, in this example, the light source is a CCFL, the embodiments of the present invention are not limited thereto. A light emitting diode (LED) may also be used as the light source, for example.

The reflecting plate 400 is provided on the lower portion of the light source part 300 in the form of a board, and serves to change the direction of light emitted from the light source part 300 to the lower portion so that the light is re-incident to the LCD panel 100. The reflecting plate 400 may be attached to the lower chassis 710 using adhesives or a double-faced adhesive tape, or may be fastened to the lower chassis 710 by screws, for example. A reflective material may be coated on the bottom surface of the lower chassis 710 instead of the reflecting plate 400.

The optical plates 500 are provided on the upper portion of the light source part 300, and include a diffusion sheet 510 and a plurality of prism sheets 520. The optical plates 500 serve to change the characteristics of light emitted from the light source part 300 to the upper portion. That is, the diffusion sheet 510 serves to diffuse the light incident from the light source part 300 so that the light has a uniform distribution in a wide range, and the prism sheets 520 serve to change the inclined incident light among the diffused lights so that the light is incident at right angles to the LCD panel 100. Here, the number of diffusion sheets 510 and prism sheets 520 that may be used is not limited. Also, either of the diffusion sheet 510 and the prism sheets 520 may be patterned to heighten the light uniformity and the light efficiency. Also, if any one of the optical plates 500 can diffuse light and change the direction of the light, it is possible to omit any one of the diffusion sheet 510 and the prism sheets 520.

The mold frame 600 is provided in the form of a rectangular frame of which upper and lower portions are open, and serves to fixedly support the LCD panel 100 and the components of the backlight assembly 2000. The LCD panel 100 is placed on the upper portion of the mold frame 600, and the optical plates 500, the light source part 300, and the reflecting plate 400 are laminated in order and placed on the inner surface of the mold frame 600.

The receiving member 3000 includes an upper chassis 720 and the lower chassis 710. The upper chassis 720 is provided in the form of a rectangular frame of which upper and lower portions are open, and has a side wall part bent downward along the edge of the rectangular frame. The upper chassis 720 is provided on the upper portion of the LCD panel 100, and fixes the LCD panel 100 placed in the mold frame 600. The lower chassis 710 is provided in the form of a rectangular frame of which upper and lower portions are open, receives and supports the lower portion of the mold frame 600 in which the LCD panel 100 and the components of the backlight assembly 2000 are received. The upper chassis 720 and the lower chassis 710 are coupled to each other to form the LCD.

On the other hand, as illustrated in FIGS. 2 and 3, a plurality of electronic components 242 are mounted on one surface of the control board 240, and the other surface of the control board 240 is placed on the rear surface of the lower chassis 710. On the upper portion of the control board 240, the shield case 250 is provided covering the control board 240 and has the opening 252 formed thereon to expose the electronic components 242 formed on one surface of the control board. Here, the shield case 250 is attached or fastened to the rear surface of the lower chassis 710 using double-faced tape or screws as it covers the control board 240. Also, the plate type member 260, which has a size equal to or greater than the opening 252 so as to cover the opening 252 formed on the shield case, is provided on the upper portion of the shield case 250.

The control board 240 is provided in the form of a rectangular board, and the plurality of electronic components 242 are mounted on one surface thereof. The electronic components 242 include a timing controller (T-CON) 242a, a memory chip 242b, capacitors 242c, resistors 242d, and the like. The timing controller 242a generates digital control signals for supplying signals to the data PCB 220a and the gate PCB 220b by controlling the timing of the externally applied analog image signal. Also, on one side of the control board 240 on which the electronic components 242 are mounted, a connector 244 for receiving the external analog signal is provided, and on the other side, flexible printed circuit connection parts 246 are provided, which transmit the digital signal converted from the analog signal applied to the control board 240 to the flexible printed circuits 230. The flexible printed circuits 230, which are bent toward the rear surface of the lower chassis 710, are connected to the data PCB 220a connected to the LCD panel 100. After the control board 240 is fixedly supported by the shield case 250, the flexible printed circuits 230 are connected to the flexible printed circuit connection parts 246.

When the signal is applied from the outside to the control board 240 through the connector 244, EMI is generated from the plurality of electronic components 242 while the control board 240 converts the external analog signal into the digital signal. In order to prevent the generated EMI from affecting the components of the LCD, the shield case 250 covering the control board 240 shields the EMI generated from the control board 240.

The shield case 250 is provided in the form of a rectangular box of which one surface is open, and includes a base 250a in the form of a rectangular plate, and a side wall part 250b bent at right angles from the end of the base 250a. In the center of the base 250a, the opening 252 is penetratingly formed, and on both sides of the base 250a, the first apertures 254 and the second aperture 256 are formed, which extend from both sides of the base 250a to the side wall part 250b, respectively.

The shield case 250 covers a surface of the control board 240, i.e., a surface of the control board on which the plurality of electronic components 242 are mounted, and includes the opening 252 formed on the base 250a of the shield case 250 facing the electronic components 242 so as to expose the electronic components 242. When the electronic components 242 and the metal shield case 250 are arranged to face each other, the EMI noise can be prevented from being generated due to the resonance generated therebetween. Also, the first apertures 254 are formed to extend from one end portion of the base 250a of the shield case 250 to the upper portion of the side wall part 250b so that the flexible printed circuits 230 can be connected to the flexible printed circuit connection parts 246 after the shield case 250 covers the control board 240. The number of the first apertures 254 is not limited, and corresponds to the number of flexible printed circuits 230 which are bent to the rear surface of the lower chassis 710 and connected to the flexible printed circuit connection parts 246.

The second aperture 256 is formed on the other side of the shield case 250 that faces the first apertures 254 formed on the shield case 250, and extends so that a portion of the side wall part 250b is exposed from the other end portion of the base 250a of the shield case 250. The second aperture 256 exposes the connector 244 that is mounted on the control board 240 to receive the external signal, and the connector 244 is fastened to an external connector (not illustrated) that transmits the external signal after the shield case 250 is fastened to the lower chassis 710 to cover the control board 240. That is, by forming the first apertures 245 and the second aperture 256, the fastening state of the flexible printed circuits 230 and the flexible printed circuit connection parts 246 and the fastening state of the connector 244 and the external connector can be easily visually confirmed.

On the shield case 250 on which the opening 252 is formed, the plate type member 260 is further provided. The plate type member 260 may be provided in the form of a rectangle to correspond to the shape of the opening 252, and may have a size equal to or larger than the size of the opening 252 to cover the opening 252. The plate type member 260 may be made of a non-metallic material, such as wood, plastic, rubber, ceramic, and the like, or an insulating material, and may be made of an insulating tape. That is, the plate type member 260 is attached to the shield case 250 so as to cover the upper portion of the electronic components 242 that are exposed to the outside through the opening 252 of the shield case 250, and thus the EMI emitted from the electronic components 242 can be reduced. Also, the plate type member 260 conceals the upper portion of the exposed control board 240, and thus the entrance of external metal components into the opening 252 of the shield case 250 can be prevented when the display device is coupled to an external device, so that the EMI noise is prevented from being generated between the electronic component 242 mounted on the control board 240 and the external metallic material.

As described above, in a conventional display device, resonance is generated between the respective electronic components mounted on the control board to generate the EMI and the metal shield case covering the control board, and thus EMI exceeding a standard value is generated in the display panel. By contrast, according to an exemplary embodiment of the present invention, since the opening 252 is formed on the shield case 250 so as to expose the electronic components 242 formed on one surface of the control board 240, the EMI generated in the control board 240 is sufficiently reduced by the metal shield case 250, and the EMI noise that may be generated between the electronic components 242 and the shield case 250, particularly, the EMI noise generated in a low frequency band, is removed to prevent the malfunction of the display panel. In addition, by providing the plate type insulating member 260 in the opening 252 formed on the shield case 250, the EMI generated from the electronic components 242 to the outside of the shield case 250 can be reduced. Also, the plate type member 260 distances the external metal material to the electronic components 242 formed on the control board 240, and thus the EMI noise generated between the electronic components 242 on the control board 240 and the neighboring external metal components can be prevented.

In order to prevent the generation of the EMI noise between the control board 240 and the shield case 250, the control board 240 and the shield case 250 may be modified as follows.

As illustrated in FIG. 4, the electronic components, such as the timing controller 242a, are mounted on one surface of the control board 240, and the other surface of the control board 240 is placed on the rear surface of the lower chassis 710. The shield case 250 covers the control board 240, and has the opening 252 formed thereon to expose the timing controller 242a mounted on the control board 240. The shield case 250 is coupled to the rear surface of the lower chassis 710 through the double-faced tape or screws as it covers the control board 240. Also, the plate type member 260, which has a size equal to or greater than the size of the opening 252 so as to cover the opening 252 formed on the shield case, is provided on the upper portion of the shield case 250.

The opening 252 formed on the base 250a of the shield case 250 is formed in a position corresponding to the timing controller 242a among the electronic components 242a mounted on the control board 240, and the size of the opening 252 is determined so that the timing controller 242a is sufficiently exposed to an upper portion of the shield case 250. The plate type insulating member 260, which is provided on the upper portion of the opening 252, is coupled to the upper portion of the opening 252 to face the upper portion of the exposed timing controller 252a. An insulating tape is used as the plate type member 260.

As described above, according to an exemplary embodiment of the present invention, the shield case 250 covers the control board 240, and thus the EMI generated from the control board 240 can be sufficiently reduced. Also, the opening 252 is formed on the shield case 250 so that the timing controller 242a mounted on the control board 240 is exposed, and thus the EMI noise generated between the timing controller 242a and the shield case 250 can be removed. In addition, since the plate type insulating member 260 is attached to the opening 252, the EMI generated from the control board 240 can be reduced, and the entrance of an external metal components into the opening 252 of the shield case 250 can be prevented when the display device is coupled to an external device, so that the EMI noise is prevented from being generated between the electronic component 242 and the external metal components.

When the EMI generated from the timing controller 242a is greater than the EMI generated from other components mounted on the control board 240 and when the metal shield case covers the timing controller 242a, there is a great possibility that the EMI noise exceeding a standard value will be generated due to the resonance between the respective electronic components and the metal shield case. Accordingly, by covering an area where the timing controller 242a is exposed with the plate type insulating member 260, the EMI generated in the timing controller 242a is reduced, and the EMI noise that may be generated between the timing controller 242a and the shield case 250, particularly, the EMI noise generated in the low frequency band, is removed to prevent the malfunction of the display panel.

In addition, as illustrated in FIG. 5, the electronic components, such as a plurality of memory chips 242b, are mounted on one surface of the control board 240, and the other surface of the control board 240 is placed on the rear surface of the lower chassis 710. The shield case 250 covers the control board 240, and has a plurality of openings 252 formed thereon to expose the memory chips 242b mounted on the control board 240. The shield case 250 is coupled to the rear surface of the lower chassis 710 to receive the control board 240. Also, a plurality of plate type members 260, having a size equal to or greater than the size of the opening 252 so as to cover the opening 252 formed on the shield case 250, are provided on one side of the shield case 250.

Two openings 252 having different sizes are formed on the base 250a of the shield case 250 so as to correspond to the position corresponding to the memory chips 242b mounted on the control board 240 and the size of the memory chips 242b. Of course, the number of openings 252 is not limited, and may correspond to the number of memory chips 242b. Also, the plate type members 260, which is provided on the upper portions of the two openings 252, are attached to the two openings 252 to face the upper portions of the memory chips 252b exposed through the openings 252. Here, instead of the two plate type members 260, a large plate type member may be formed to cover both of the two openings 252. An insulating tape is used as the plate type member 260.

As described above, according to an embodiment of the present invention, since a plurality of openings 252 are formed on the shield case 250 so as to expose a plurality of memory chips 242b mounted on the control board 240, and plate type insulating members 260 are attached to face the exposed memory chips 242b, the EMI generated from the control board 240 can be sufficiently reduced, and the EMI noise of the low frequency band generated between the memory chips 242b and the shield case 250 can be removed. Particularly, when the EMI generated from the memory chips 242b is great next to the timing controller 242a and when the metal shield case covers the timing controller 242a, there is a great possibility that the EMI noise exceeding a standard value may be generated due to the resonance between the respective electronic components and the metal shield case. The described structure according to an exemplary embodiment of the present invention can remove the EMI noise generated in the display panel below the standard value.

Although a technique of lowering the EMI noise below the standard level by providing the plate type insulating members 260 facing the area of the shield case 250 corresponding to the timing controller 242a and the memory chips 242b mounted on the control board 240 has been described, the present invention is not limited thereto. The opening 252 may be formed on the shield case 250 to expose capacitors 242c and resistors 242b, and the plate type insulating member 260 may be provided in a portion facing the exposed capacitors 242c and the resistors 242d, so that the EMI generation is reduced and the EMI noise generation is prevented. Although, by way of example, that the plate type insulating member 260 is attached to an upper portion of the shield case 250 to cover the opening 252, the present invention is not limited thereto. It is also possible to attach the plate type member 260 to the lower portion of the shield case 250 to cover the opening 252.

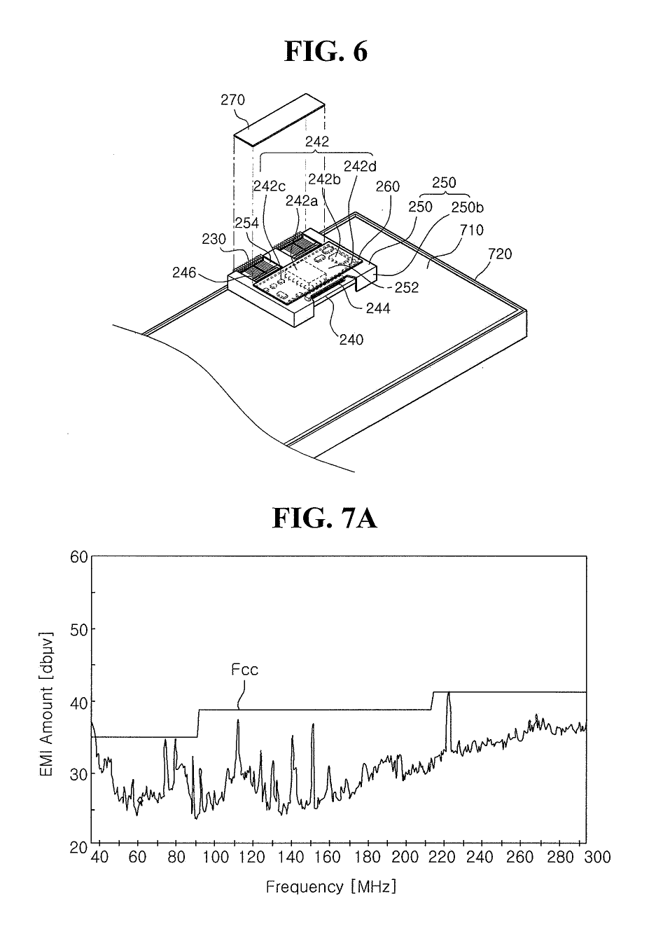

Also, as illustrated in FIG. 6, the plurality of electronic components 242 and the flexible printed circuit connection parts 246 may be mounted on one surface of the control board 240, and on one side of the control board 240, the shield case 250 is fastened to the rear surface of the lower chassis 710 to cover the one surface of the control board 240. The opening 252 is formed on the shield case 250 to expose the plurality of electronic components 242, and the first apertures 254 are formed to expose the flexible printed circuit connection part 246. Also, the first plate type member 260 and the second plate type member 270 are provided to cover the opening 252 and the first apertures 254 formed on the shield case 250.

The first plate type member 260 is attached to a position facing the electronic components 242 exposed to an upper portion of the opening 252 formed on the shield case 250, and the second plate type member 270 is attached to the first apertures 254 to cover the flexible printed circuit connection parts 246 exposed to the upper portion of the first apertures formed on the shield case 250 and the flexible printed circuits 320 connected to the flexible printed circuit connection parts 246. Here, the second plate type member 270 may be in the form of a rectangular plate to cover the exposed flexible printed circuit connection parts 254 and the flexible printed circuits 230 connected thereto, or a plurality of second plate type members may be provided to correspond to the plurality of flexible printed circuit connection parts 246. A metal member or an insulating member may be used as the second plate type member 270.

When the second plate type member 270 is the metal member, the second plate type member 270 seals up the first apertures 254 of the shield case 250 so as to cover the flexible printed circuit connection parts 246 connected to the flexible printed circuits 230. The second plate type member 270 may be a metal member, such as aluminum or magnesium. The above-described structure shields the EMI generated from the flexible printed circuit connection parts 246 that is a connection region between the flexible printed circuits 230 and the control board 240, and thus the EMI generated in the LCD is reduced to prevent the malfunction of the display panel.

On the other hand, in the case where the second plate type member 270 is the insulating member, the second plate type member 270 seals up the first apertures 254 of the shield case 250 so as to cover the flexible printed circuit connection parts 246 connected to the flexible printed circuits 230 in the same manner. The second plate type member 270 may be a metal member, such as wood, plastic, rubber, ceramic, and the like, and may be an insulating tape. The above-described structure protects the flexible printed circuit connection parts 246 and the flexible printed circuits 230 connected thereto, and thus the flexible printed circuit connection parts 246 and the flexible printed circuits 230 connected thereto are prevented from being damaged. Also, the above-described structure reduces the EMI generated in the flexible printed circuit connection parts 246 and the flexible printed circuits 230 connected thereto to prevent the malfunction of the display panel.

Hereinafter, experimental results of exemplary embodiments of the present invention will be described in more detail.

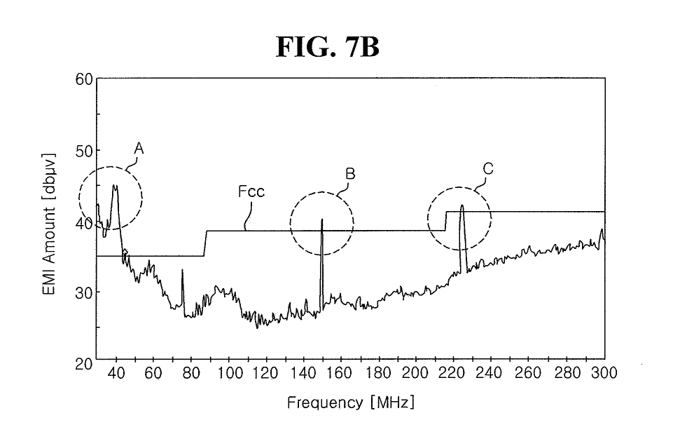

FIGS. 7A and 7B are graphs showing results of EMI tests performed on the flat display device according to an exemplary embodiment of the present invention and on a conventional LCD.

In the experiment, the opening 252 was formed on the shield case 250 to expose the plurality of electronic components 242 mounted on the control board 240 as in an exemplary embodiment of the present invention, a 52-inch TV having an LCD in which the non-metallic plate type member 260 was fastened to the opening 252 was prepared, and the EMI characteristic thereof was tested. That is, the 52-inch TV was accommodated in an EMI chamber, and an experimental frequency was applied at a distance of three meters from the 52-inch TV accommodated in the EMI chamber. Here, the frequency was gradually increased in the frequency range of 30 MHz to 300 MHz, and vertical components of EMI were measured. On the other hand, as a comparative example, the amount of EMI was measured under the same condition as the above-described experiment except that no opening was formed on the shield case. In FIGS. 7A and 7B, the horizontal axis represents the frequency band applied to the 52-inch TV, and the vertical axis represents the amount of EMI generated in the LCD. Also, the solid line in the graph indicates US EMI Standards (FCC).

In FIG. 7B are the results of the conventional display device, the amount of EMI generated in the LCD in the entire frequency band of 30 MHz to 300 MHz appears to be somewhat lower than that permitted by US EMI Standards (FCC). However, in specified frequency bands of 30 MHz to 45 MHz (A), 140 MHz to 150 MHz (B), and 220 MHz to 230 MHz (C), it can be seen that EMI noise exceeding the value permitted by US EMI Standards (FCC) is generated, and particularly in the frequency band of 30 MHz to 45 MHz (A), the EMI noise is most increased over the value permitted by US EMI Standards (FCC).

By contrast, in FIG. 7A are the results of an exemplary embodiment of the present invention, the amount of EMI generated in the frequency band of 30 MHz to 300 MHz appears to be lower than that permitted by US EMI Standards (FCC). In the specified frequency bands of 30 MHz to 45 MHz, 140 MHz to 150 MHz, and 220 MHz to 230 MHz, and particularly in the frequency band of 30 MHz to 45 MHz, it can be confirmed that the EMI noise is notably below the value permitted by US EMI Standards (FCC).

According to an exemplary embodiment of the present invention, since the shield case 250, on which the opening 252 is formed to expose electronic components 242 mounted in the control board 240, is coupled to the control board 240 and the plate type member 260 is provided to cover the exposed electronic components 242, the amount of EMI generated by the control board 240 can be reduced, and simultaneously, the EMI noise generated between the control board 240 and the shield case 250 can be removed. Accordingly, the EMI generated by the control board 240 is maintained below US EMI Standards (FCC) in the low frequency band, and thus a malfunction of the display panel can be prevented.

In the foregoing description, an LCD has been used as an example. However, the EMI shielding according to exemplary embodiments of the present invention can be applied to other display devices, such as a plasma display panel (PDP), a field emission display (FED), an organic light emitting diode (OLED), and the like. Further, it is also possible to apply the present invention to electronic devices different than the display devices discussed above.

By forming the opening in the shield case corresponding to the electronic components mounted on the control board, the amount of EMI can be minimized, and the EMI noise that may be generated between a control board and the shield case can be removed.

Also, by installing a plate type member in the opening formed on the shield case, the EMI noise that may be generated between the components and other metal components neighboring the control board can be removed.

Also, by attaching the plate type member to the flexible printed circuit connection parts connected to the flexible printed circuits, the amount of EMI generated in the control board can be reduced.

Although exemplary embodiments of the present invention have been described for illustrative purposes, those skilled in the art will appreciate that various modifications, additions and substitutions are possible, without departing from the scope and spirit of the disclosure.

What is claimed is:

1. A control board assembly comprising:
a board;
at least one electronic component mounted on one surface of the board; and
a shield case receiving therein the board on which the at least one electronic component is mounted;
wherein on a surface of the shield case facing the at least one electronic component, at least one opening is formed to expose the at least one electronic component.

2. The control board assembly of claim 1, further comprising a first plate type member provided on a side of the opening to cover the opening, wherein the first plate type member is made of an insulating material.

3. The control board assembly of claim 2, wherein the board comprises a connection part formed on a side of the surface of the board to transmit external signals; and the shield case comprises a first aperture formed therein to expose the connection part.

4. The control board assembly of claim 3, further comprising a second plate type member provided on a side of the first aperture to cover the first aperture, wherein the second plate type member comprises one of a metal member and an insulating member.

5. The control board assembly of claim 4, wherein the shield case and the first and second plate type members are coupled to each other.

6. The control board assembly of claim 1, wherein the electronic component comprises a timing controller.

7. A display device comprising:
a display panel displaying an image;
a control board providing drive signals to the display panel and having an electronic component mounted on a surface thereof; and
a shield case receiving therein the control board;
wherein on a surface of the shield case facing the electronic component, an opening is formed so as to expose the electronic component.

8. The display device of claim 7, further comprising a first plate type member formed on a side of the opening to cover the opening.

9. The display device of claim 8, wherein the first plate type member is an insulating member.

10. The display device of claim 9, wherein the first plate type member is an insulating tape.

11. The display device of claim 10, wherein the electronic component comprises a timing controller.

12. The display device of claim 7, further comprising a connection part formed on a side of the surface of the board to transmit external signals.

13. The display device of claim 12, wherein the shield case comprises a first aperture formed therein to expose the connection part.

14. The display device of claim 13, further comprising a second plate type member provided on a side of the first aperture to cover the first aperture.

15. The display device of claim 14, wherein the second plate type member comprises one of a metal member and an insulating member.

16. The display device of claim 7, wherein a plurality of electronic components are mounted on the board, and the opening is formed to expose the plurality of electronic components.

17. The display device of claim 16, wherein the opening is formed to correspond to the number of electronic components.

18. The display device of claim 17, further comprising a third plate type member provided on a side of the shield case to cover the opening.

19. The display device of claim 18, wherein the shield case and the plate type member are unitarily formed.

20. The display device of claim 19, wherein an aperture is formed on the shield case in an area corresponding to the connection part.
